(19) United States
(12) Patent Application Publication
(10) Pub. No.: US 2025/0123325 A1
(43) Pub. Date: Apr. 17, 2025

(54) ELECTRICAL CONNECTING APPARATUS

(71) Applicant: KABUSHIKI KAISHA NIHON MICRONICS, Tokyo (JP)

(72) Inventor: KEN HASEGAWA, TOKYO (JP)

(21) Appl. No.: 18/817,786

(22) Filed: Aug. 28, 2024

(30) Foreign Application Priority Data
Oct. 12, 2023 (JP) 2023-176836

(51) Int. Cl. G01R 31/28

(52) U.S. Cl. CPC G01R 31/2889

(57) ABSTRACT

A large amount of current can be allowed, many short power supply paths and ground paths can be formed, and a wiring resistance can be significantly reduced.

An electrical connecting apparatus that electrically connects a testing device and a test subject includes a multilayer wiring substrate having a plurality of contactors that electrically contact electrode terminals of the test subject and electrically connect substrate electrodes connected to the testing device and the electrode terminals, in which the multilayer wiring substrate has a metal core member, and the metal core member is arranged at a position where one or both of a power supply terminal and a ground terminal of the electrode terminals of the test subject are present.

### CROSS-REFERENCE TO RELATED APPLICATIONS

The present application claims priority under 35 U.S.C. 119 to Japanese Patent Application No. 2023-176836 filed on Oct. 12, 2023. The contents of this application are incorporated herein by reference in their entirety.

### TECHNICAL FIELD

The present disclosure relates to an electrical connecting apparatus, which can be, for example, applied to electrical connecting apparatus such as probe cards used for electrical testing such as electrical tests of semiconductor integrated circuits formed on semiconductor wafers.

### BACKGROUND ART

For example, semiconductors for AI (Artificial Intelligence) processing consume more power due to an increase in transistors, and tests in which all transistors are operated simultaneously may be performed.

In addition, area-array-type elements have a large number of electrode terminals (PADs), so the amount of current that flows instantaneously is expected to be high. For example, there is a demand for an allowable current of more than 1000 A, but conventional probe cards are not able to keep up with this.

Conventionally, a method of providing busbars on a substrate to efficiently pass a large amount of current to a target location is known. Busbars have a low electrical resistance and can pass a large amount of current.

Also, PTL 1 describes a method of filling through-holes in a PCB substrate with copper to reduce a wiring resistance.

### CITATION LIST

### Patent Literature

### [PTL 1]

Japanese Patent Application Publication No. 2006-339349

### SUMMARY OF INVENTION

### Technical Problem

However, a space transformer (ST) substrate used in the probe card must be thin because it has a high wiring density and requires fine circuits. Therefore, layers cannot be occupied only by specific power supply paths and ground (GND) paths. In addition, since heat is generated by Joule heat, if measures are insufficient, the product will be destroyed.

When using busbars, a structure in which a copper plate is attached to the upper surface of the substrate is considered. However, if the busbar is attached all the way to the lower surface of the substrate, it will affect the layout of the probe. Furthermore, since the ST substrate needs to be thin and also needs to be wired for IOs and other power supplies, it is difficult to provide busbars on the inner layer of the ST substrate.

Furthermore, as in PTL 1, it is difficult to meet customer demands for current exceeding 1000 A by merely filling the through-holes with copper.

Therefore, there is a demand for an electrical connecting apparatus that can allow a large amount of current, form many short power supply paths and ground paths, and significantly reduce a wiring resistance.

### Solution to Problem

To solve the problem, the present disclosure provides an electrical connecting apparatus that electrically connects a testing device and a test subject, including a multilayer wiring substrate having a plurality of contactors that electrically contact electrode terminals of the test subject and electrically connect substrate electrodes connected to the testing device and the electrode terminals, in which the multilayer wiring substrate has a metal core member, and the metal core member is arranged at a position where one or both of a power supply terminal and a ground terminal of the electrode terminals of the test subject are present.

### Advantageous Effects of Invention

According to the present disclosure, it is possible to allow a large amount of current, form many short power supply paths and ground paths, and significantly reduce a wiring resistance.

### BRIEF DESCRIPTION OF DRAWINGS

FIG. 1 is a diagram showing the configuration of a probe substrate according to an embodiment.

FIG. 2 is a diagram showing the configuration of an electrical connecting apparatus according to an embodiment.

FIG. 3 is an explanatory diagram explaining the positional relationship between the electrode terminals of a test subject and core members in an embodiment.

FIG. 4 is a first diagram showing the configuration of a probe substrate according to a modified embodiment.

FIG. 5 is a second diagram showing the configuration of a probe substrate according to a modified embodiment.

### DESCRIPTION OF EMBODIMENTS

### (A) Main Embodiment

Below, an embodiment of the electrical connecting apparatus according to the present disclosure will be described in detail with reference to the drawings.

In this embodiment, an example is shown in which the electrical connecting apparatus according to the present disclosure is applied to a probe card attached to a tester in order to inspect the electrical characteristics specified in a plurality of semiconductor integrated circuits formed on a semiconductor wafer.

### (A-1) Configuration of Electrical Connecting Apparatus

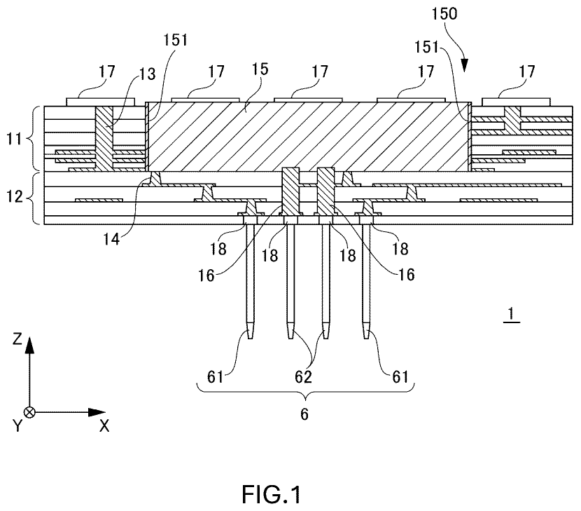

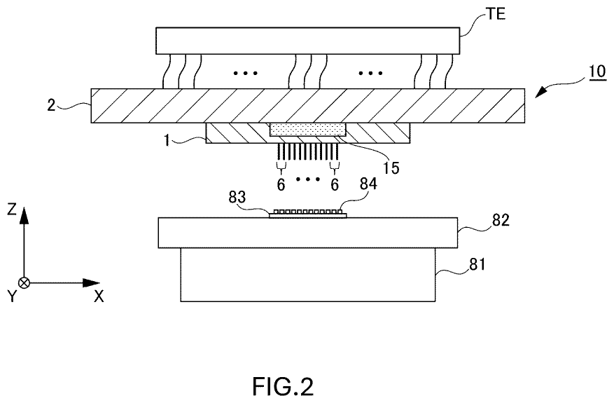

FIG. 2 is a diagram showing the configuration of the electrical connecting apparatus according to the embodiment. FIG. 1 is a diagram showing the configuration of the probe substrate according to the embodiment.

In FIG. 2, the electrical connecting apparatus 10 according to the embodiment has a probe substrate 1 and a wiring substrate 2. The probe substrate 1 is provided on the lower surface of the wiring substrate 2.

Note that although FIGS. 1 and 2 show the main components of the electrical connecting apparatus 10, the components of the apparatus are not limited to those shown in the drawings and also include components that are not actually shown.

The electrical connecting apparatus 10 transmits and receives electrical signals between a test subject 83 and a tester (testing device) TE. The electrical connecting apparatus 10 has electrical contactors (probes) 6 that electrically contact electrode terminals 84 of the test subject 83. For example, the electrical connecting apparatus 10 can be applied to a probe card or the like, and in this case, a vertical probe card is illustrated.

The electrical connecting apparatus 10 is attached to the test head of the tester TE, and during an inspection, the corresponding electrical contactors 6 are electrically connected to the electrode terminals 84 of the test subject 83, thereby electrically connecting the tester TE and the test subject 83.

That is, during the inspection, the electrical connecting apparatus 10 supplies an electrical signal from the tester TE to the electrode terminals 84 of the test subject 83 through the electrical contactors 6, and the electrical connecting apparatus 10 also supplies an electrical signal from the test subject 83 to the tester TE through the electrical contactors 6. In this way, the electrical connecting apparatus 10 electrically connects the test subject 83 and the tester TE, so that the tester TE can inspect the electrical characteristics of the test subject 83.

The test subject 83 is an object whose electrical characteristics are inspected by the tester TE. For example, the test subject 83 is a semiconductor integrated circuit formed on a semiconductor wafer before housing. In particular, in this embodiment, the test subject 83 is assumed to have a large number of transistors such as AI processing compatible semiconductor integrated circuits (IC chip devices), and have a high allowable current during the inspection. The shape of the test subject 83 is not particularly limited, and may be, for example, a rectangle, a triangle, or the like when viewed from above.

The test subject 83 is, for example, placed on the upper surface of a chuck 82 connected to a driving unit 81 such as a multi-axis stage, and the position of the test subject 83 on the chuck 82 can be adjusted by driving the driving unit 81. During the inspection, the test subject 83 on the chuck 82 and the electrical contactors 6 of the electrical connecting apparatus 10 are brought relatively close to each other so that the electrode terminals 84 of the test subject 83 and the corresponding electrical contactors 6 are in electrical contact.

### [Wiring Substrate 2]

The wiring substrate 2 is a substantially circular, plate-shaped printed circuit substrate made of a synthetic resin material such as polyimide. The wiring substrate 2 is an example of a first substrate.

Printed wiring is formed on one surface (for example, the upper surface) of the wiring substrate 2, and electronic components such as resistors and capacitors are provided. The outer edge of the wiring substrate 2 is provided with a plurality of tester connection parts (not shown) for connection to the electrical circuit of the tester TE, and each tester connection part is connected to the printed wiring on the wiring substrate 2.

For example, the wiring substrate 2 is formed with a plurality of through-holes penetrating in the substrate thickness direction (Z-axis direction). Conductive connectors in are inserted into the through-holes and connected to the connection terminals 17 on the probe substrate 1. This allows electrical connection between the wiring substrate 2 and the probe substrate 1 present on the lower surface of the wiring substrate 2 through the conductive connectors.

### [Probe Substrate 1]

The probe substrate 1 is a substrate that supports a plurality of electrical contactors 6. The probe substrate 1 is also called a probe head and is an example of a second substrate. In this embodiment, the probe substrate 1 supports a vertical probe as the electrical contactor 6, but the electrical contactor 6 is not limited to this.

The probe substrate 1 is, for example, a multilayer substrate made of a synthetic resin material such as polyimide, and a wiring path is formed between the plurality of substrates.

The electrical contactor 6 is a vertical probe, but may be a cantilever probe. The other end (for example, the upper end) of the electrical contactor 6 is connected to a connection terminal 18 provided on one surface (for example, the lower surface) of the probe substrate 1, and during the inspection, one end (for example, the lower end) of the electrical contactor 6 is electrically connected to the electrode terminal 84 of the test subject 83.

### (A-2) Probe Substrate 1

In FIG. 1, the probe substrate 1 is roughly divided into a first multilayer wiring layer 11 and a second multilayer wiring layer 12.

The shapes of the first multilayer wiring layer 11 and the second multilayer wiring layer 12 are not particularly limited, but are formed, for example, in the shape of a rectangular plate when viewed from above.

In the probe substrate 1, the first multilayer wiring layer 11 is a substrate formed of a plurality of layers, and a first signal circuit 13 is formed between the plurality of substrates as a wiring path. The first signal circuit 13 can be electrically connected to the wiring substrate 2 through a connection terminal 17 connected to the wiring substrate 2. The thicknesses of the substrates of each layer forming the first multilayer wiring layer 11 may be the same or different, and the layers are bonded with a bonding material such as an adhesive.

In addition, the first multilayer wiring layer 11 formed of a plurality of substrates has a through-hole 150 formed in its approximate center from one surface to the other surface, and the through-hole 150 is provided with a core member 15 made of copper.

A method of inserting the core member 15 into the through-hole 150 is not particularly limited. For example, a method can be used in which the through-hole 150 is formed in the first multilayer wiring layer 11, the core member 15 is inserted into the through-hole 150, and a wall surface 151 of the through-hole 150 and the outer peripheral surface of the core member 15 are bonded with an adhesive or the like. In the state of being inserted into the through-hole 150, the core member 15 is flush with both sides of the first multilayer wiring layer 11. In other words, the core member 15 is provided so that no steps are formed.

The core member 15 is a member formed of a conductive metal such as copper or a copper alloy. The shape of the core member 15 can be a polygonal prism such as a cylinder, an elliptical cylinder, a triangular prism, or a square prism. In this embodiment, it is assumed that the core member 15 is a cylindrical member formed of copper.

The material of the core member 15 is not limited to copper, and may be other metals as long as the resistance is small and a large amount of current can be allowed. In addition, the surface of the core member 15 may be covered with a metal film (for example, a gold film) to prevent oxidation.

In the probe substrate 1, the second multilayer wiring layer 12 is a substrate formed of a plurality of layers, and is provided on the other surface (for example, the lower surface) of the first multilayer wiring layer 11 on which the core member 15 is provided. The thicknesses of the substrates of each layer forming the second multilayer wiring layer 12 may be the same or different.

A plurality of electrical contactors 6 is provided on the other surface (for example, the lower surface) of the second multilayer wiring layer 12.

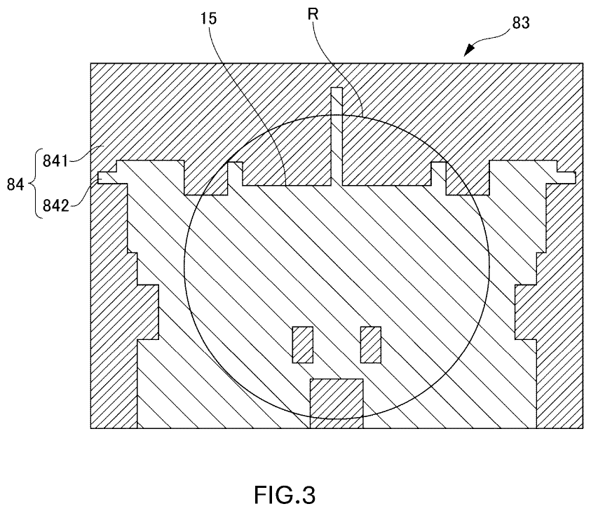

Here, as illustrated in FIG. 3, when the test subject 83 is an area-array-type IC chip device, the electrode terminals 84 of the test subject 83 are formed in a lattice pattern.

As shown in FIG. 3, the test subject 83 has, as electrode terminals 84, a signal terminal 841 and a power supply terminal (VDD-PAD) or a ground terminal (GND-PAD) 842. For convenience of explanation, the latter electrode terminal is called a power supply or ground electrode terminal 842.

Thus, the test subject 83 has two types of electrode terminals 84, and in accordance with these types, the electrical contactors 6 include a signal contactor 61 that electrically contacts the signal terminal 841 and a power supply or ground contactor 62 that electrically contacts the power supply or ground electrode terminal 842.

The second multilayer wiring layer 12 has a second signal circuit 14 formed as a wiring path between a plurality of substrates, and the second signal circuit 14 is connected to the signal contactor 61 of the electrical contactors 6 and is also connected to the first signal circuit 13 of the first multilayer wiring layer 11. That is, the first signal circuit 13 is electrically connected to the signal contactor 61 through the second signal circuit 14.

In other words, during the inspection, the signal contactor 61 is electrically connected to the signal terminal 841 of the test subject 83, and an electrical signal to the signal terminal 841 of the test subject 83 is transmitted and received through the first signal circuit 13, the second signal circuit 14, and the signal contactor 61.

In addition, the second multilayer wiring layer 12 has vias 16 formed as through-connection paths connecting the core member 15 provided in the first multilayer wiring layer 11 and the power supply or ground contactor 62.

Since the core member 15 has a low resistance and is a conductor that allows a large amount of current, a large amount of current can be supplied to the test subject 83 by connecting the core member 15 and the power supply or ground contactor 62 through the vias 16. In other words, even when a large amount of current flows instantaneously during the inspection of the test subject 83, it is possible to keep up with this.

The core member 15, the power supply or ground contactor 62, and the power supply or ground electrode terminal 842 of the test subject 83 are in such a positional relationship that they correspond to each other in the Z-axis direction as shown in FIG. 3.

That is, the power supply or ground contactor 62 and the core member 15 are located directly above the power supply or ground electrode terminal 842, so that the conduction path through the via 16 can be made the shortest. In this way, the wiring resistance including the via 16 can be greatly reduced, and a large amount of current can be passed.

In other words, the power supply or ground electrode terminal 842 present in the area (existence area) R directly below the core member 15 is conducted to the power supply or ground contactor 62 through the via 16 in the shortest path.

On the other hand, for the power supply or ground electrode terminal 842 that is outside the area (existence area) R directly below the core member 15, the second signal circuit 14 of the second multilayer wiring layer 12 is connected to the power supply or ground contactor 62, and conduction is established through the second signal circuit 14 and the power supply or ground contactor 62.

### (A-3) Effects of Embodiment

As described above, according to this embodiment, the probe substrate 1 is formed by bonding the first multilayer wiring layer 11 provided with the core member 15 to the second multilayer wiring layer 12 on its lower surface, and the conduction path is shortened through the via 16 to efficiently conduct a large amount of current to the power supply or ground contactor 62 within the existence area R of the core member 15. As a result, it is possible to handle inspections even if the allowable current value is large.

In addition, according to this embodiment, a core member is provided in the first multilayer wiring layer 11 of the probe substrate 1, and the second multilayer wiring layer 12 is further provided on the lower surface thereof. Therefore, even in a probe substrate that requires high wiring density and must be thin, a core member equivalent to busbars can be provided.

### (B) Other Embodiments

Various modified embodiments have been mentioned in the above-mentioned embodiment, but the present disclosure can also be applied to the following modified embodiments.

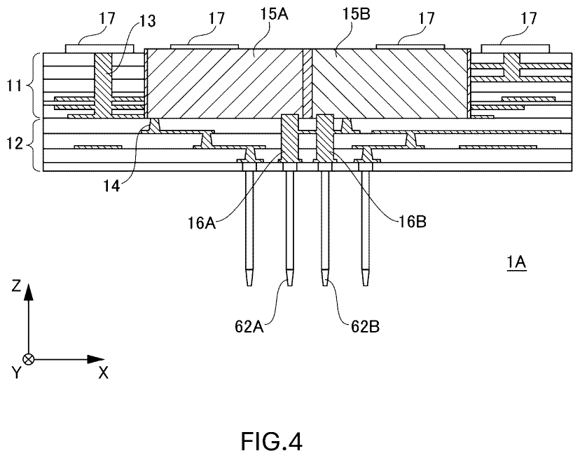

(B-1) FIG. 4 is a configuration diagram showing the configuration of a probe substrate according to a modified embodiment.

The above-mentioned probe substrate 1 in FIG. 1 is an example of a case where one core member 15 is provided, but the probe substrate 1A illustrated in FIG. 4 is an example of a case where a power supply core member 15A and a ground core member 15B are provided.

When two core members (power supply core member 15A and ground core member 15B) are provided in this way, a power supply via 16A connecting the power supply contactor 61A and the power supply core member 15A, and a ground via 16B connecting the ground contactor 61B and the ground core member 15B are provided, and current can be passed separately for power supply and ground. In this way, it is possible to handle different potentials for power supply and ground.

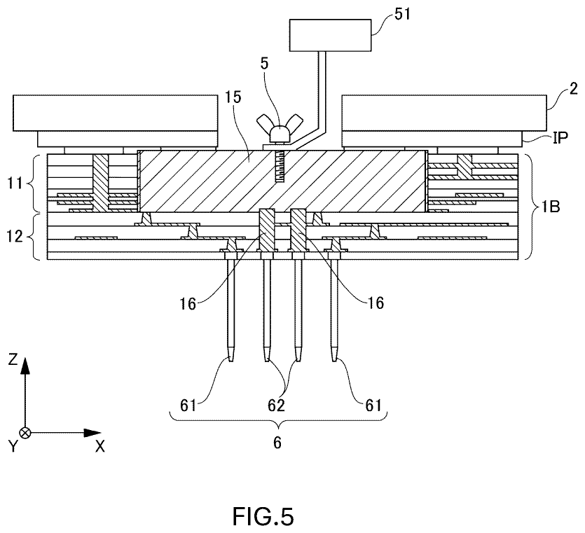

(B-2) FIG. 5 is a configuration diagram showing the configuration of a probe substrate according to a modified embodiment.

In the above-mentioned embodiment, the wiring substrate 2 and the probe substrate 1 are electrically connected, and a large amount of current is supplied from the wiring substrate 2 to the core member 15.

In contrast, the probe substrate 1B in FIG. 5 has a new connection terminal 5 on the core member 15, and supplies current from the newly provided power supply 51 to the connection terminal 5. In this way, it is possible to newly form a power supply and ground circuit including the power supply 51.

For example, by fixing a screw from the top of the core member 15, using the screw as the connection terminal 5, and connecting it to the power supply 51 with a thick wire, it is possible to handle a large amount of current.

### REFERENCE SIGNS LIST

10 Electrical connecting apparatus
2 Wiring substrate
5 Connection terminal
1, 1A, 1B Probe substrate
11 First multilayer wiring layer
12 Second multilayer wiring layer
13 First signal circuit
14 Second signal circuit
15 Core member
15A Power supply core member
15B Ground core member
16 Via
16A Power supply via
16B Ground via
17 Connection terminal
18 Connection terminal
6 Electrical contactor
61 Signal contactor
61A Power supply contactor
61B Ground contactor
62 Ground contactor
51 Power supply
81 Driving unit
82 Chuck
83 Test subject
84 Electrode terminal
150 Through-hole
151 Wall surface
841 Signal terminal
842 Electrode terminal

1. An electrical connecting apparatus that electrically connects a testing device and a test subject, comprising:
a multilayer wiring substrate having a plurality of contactors that electrically contact electrode terminals of the test subject and electrically connect substrate electrodes connected to the testing device and the electrode terminals, wherein
the multilayer wiring substrate has a metal core member, and
the metal core member is arranged at a position where one or both of a power supply terminal and a ground terminal of the electrode terminals of the test subject are present.

2. The electrical connecting apparatus according to claim 1, wherein
the multilayer wiring substrate includes:
a first multilayer wiring layer having a first signal circuit between a plurality of substrate layers and a through-hole in which the metal core member is provided; and
a second multilayer wiring layer having a second signal circuit between a plurality of substrate layers on one side of the first multilayer wiring layer, and
the second multilayer wiring layer has a through-connection path that electrically connects the metal core member and each of a power supply contactor that contacts the power supply terminal and a ground contactor that contacts the ground terminal, for each of the power supply terminal and the ground terminal within an area where the metal core member is present.

3. The electrical connecting apparatus according to claim 2, wherein
the second multilayer wiring layer is connected to the power supply terminal and the ground terminal through the first signal circuit and the second signal circuit, for each of the power supply terminal and the ground terminal outside the area where the metal core member is present.
